(19) United States
(12) Patent Application Publication
(10) Pub. No.: US 2012/0132922 A1
(43) Pub. Date: May 31, 2012

(54) COMPOSITE SUBSTRATE WITH CRYSTALLINE SEED LAYER AND CARRIER LAYER WITH A COINCIDENT CLEAVAGE PLANE

(75) Inventors: Chantal Arena, Mesa, AZ (US); Christiaan Werkhoven, Gilbert, AZ (US)

(73) Assignee: SOITEC, Crolles Cedex (FR)

(21) Appl. No.: 13/382,806

(22) PCT Filed: Jul. 8, 2009
(86) PCT No.: PCT/IB2009/006219

§ 371 Date: Feb. 15, 2012

(51) Int. Cl. H01L 21/18; H01L 29/20

(52) U.S. Cl. 257/76; 438/34; 257/E21.085; 257/E29.089

(57) ABSTRACT

A structure and a method can provide a crystalline seed layer material, such as GaN, on a crystalline carrier material, such as sapphire, aligned such that a common crystal plane exists between the two materials. The common crystal plane may provide for a fracture surface along a cleavage plane that may be oriented to be perpendicular to the top surface of an optoelectronic device as well as perpendicular to a light emission direction.

### CROSS-REFERENCE TO RELATED APPLICATION

This is a national phase entry under 35 U.S.C. §371 of International Patent Application PCT/IB2009/006219, filed Jul. 8, 2009, published in English as International Patent Publication WO 2011/004211 A1 on Jan. 13, 2011, the entire disclosure of which is hereby incorporated herein by this reference.

### TECHNICAL FIELD

This disclosure relates generally to semiconductor devices and device fabrication, such as composite substrates for light-emitting devices such as diode lasers.

### BACKGROUND

Homogenous semiconductor substrates essentially comprise a single material such as, for example, silicon (Si), germanium (Ge) and gallium arsenide (GaAs) and may come in the form of disc-shaped wafers. Homogenous semiconductor wafers, and semiconductor devices that can be formed upon the wafers, can be divided into separate die or pieces by cleavage along well-defined, predetermined crystal planes. Such cleavage may take place along planes of relative weakness and can be achieved by inscribing marks or lines into a surface of the wafers along the well-defined, predetermined crystal planes.

In addition to wafer division and separation, the technique of crystal cleavage may be utilized for fabrication of laser diode mirror facets. The mirror facets of laser diodes are commonly atomically flat and precisely aligned parallel to one another to ensure operational efficiency of the lasing devices. Such precision of alignment and flatness of laser diode mirror facets is commonly achieved by cleavage along parallel crystal planes of relative weakness. Alternative methods for producing laser diode mirror facets, such as, for example, etching and ion implantation, may produce rough misaligned facets that may be non-ideal for lasing applications.

Heterogeneous semiconductor substrates, commonly referred to as “composite substrates,” comprise two or more materials such as, for example, gallium nitride on sapphire and gallium arsenide on sapphire and may be utilized for further materials growth and device formation for improving performance, quality and flexibility. Composite substrates can be utilized for the creation of semiconductor devices such as light-emitting devices (e.g., light-emitting diodes (LEDs) and laser diodes (LDs)).

Composite substrates and devices formed utilizing such composite substrates may include column III materials such as aluminum (Al), gallium (Ga) and indium (In) in combination with column V materials such as nitrogen (N), phosphorous (P) and arsenic (As). For example, nitride compounds of column III materials can be semiconductors (known as III-nitrides) and can form composite substrates and light-emitting devices. III-nitride materials (such as gallium nitride (GaN), indium nitride (InN), aluminum nitride (AlN) and alloys thereof) can be used to produce light-emitting devices.

Certain semiconductor materials, such as III-nitride materials, can be complex to manufacture as free-standing (FS) layers, as compared to relatively less complex to manufacture semiconductors such as silicon and germanium, or compound semiconductors such as gallium arsenide (GaAs). Thus, it is known to form a number of semiconductor materials, such as III-nitride materials, as semiconductor layers on carrier substrates, such as sapphire (Al₂O₃), silicon carbide (SiC), Si and GaAs. The carrier substrate can comprise a mono-crystalline material (as well as poly-crystalline and amorphous materials) and the semiconductor layers can be formed on such carrier substrates utilizing growth, deposition, bonding and transfer techniques.

Improved composite substrates, methods of formation of composite substrates, and the use of such substrates in forming light-emitting devices such as diode lasers, are desired to improve fabrication yield and decrease costs.

### BRIEF DESCRIPTION OF THE DRAWINGS

FIG. 1 illustrates a fractured grown composite substrate according to various embodiments;

FIG. 2 illustrates a fractured bonded composite substrate formed according to various embodiments;

FIG. 3A illustrates a fractured grown composite substrate formed according to various embodiments;

FIG. 3B illustrates a fractured bonded composite substrate formed according to various embodiments;

FIG. 4 illustrates a composite substrate formed according to various embodiments;

FIG. 5 illustrates a simplified block diagram of a controller coupled to an electronic device, according to various embodiments; and

FIG. 6 illustrates an electronic system having devices formed in accordance with various embodiments.

### DETAILED DESCRIPTION

The following detailed description refers to the accompanying drawings that show, by way of illustration, specific aspects and embodiments in which the present invention may be practiced. These embodiments are described in sufficient detail to enable those skilled in the art to practice the present invention. Other embodiments may be utilized and structural, logical, and electrical changes may be made without departing from the scope of the present invention. The various embodiments are not necessarily mutually exclusive, as some embodiments can be combined with one or more other embodiments to form new embodiments.

The terms “wafer” and “substrate” as used in the following description may include any structure having an exposed surface with which to form active devices such as optical emission devices, diodes, transistors, integrated circuits (ICs), or passive devices such as resistors and capacitors. The term “substrate” is understood to include semiconductor wafers, both simple semiconductors formed of a single material, compound semiconductors formed of several materials, or composite substrates formed of multiple layers, either grown upon or attached or bonded either directly or indirectly to one another. The term “substrate” is also used to refer to semiconductor structures during processing and may include other layers that have been fabricated thereupon. Both “wafer” and “substrate” include doped and undoped semiconductors, epitaxial semiconductor layers supported by a base semiconductor or insulator, polycrystalline and amorphous materials, as well as other semiconductor structures well known to one skilled in the art. The term “conductor” is understood to generally refer to materials that allow electrical signals to propagate, and include n-type and p-type semiconductors. The terms “insulator” and “dielectric” include any material that is less electrically conductive than materials referred to as conductors or as semiconductors.

The term “horizontal” as used in this application is defined as a plane parallel to the conventional plane or surface of a wafer or substrate, regardless of the physical orientation of the wafer or substrate. The term “vertical” refers to a direction perpendicular to the horizontal as defined above. Prepositions, such as “on,” “side” (as in “side wall”), “higher,” “lower,” “over,” and “under” are defined with respect to the conventional plane or surface being on the top surface of the wafer or substrate, regardless of the orientation of the wafer or substrate. The following detailed description is, therefore, not to be taken in a limiting sense, and the scope of the present invention is defined only by the appended claims, along with the full scope of equivalents to which such claims are entitled.

The embodiments of the invention have applications to the formation of a wide range of composite substrates utilizing a broad array of materials and the formation of subsequent semiconductor device structures. For example, it can be applied to producing composite substrates and devices comprising elemental semiconductor materials such as silicon and germanium as well combinations of silicon and/or germanium. It can also be applied to group II-VI, group IV and group III-V compound semiconductor materials. Particular applications are related to formation of pure or mixed III-nitride composite substrates and device fabricated thereon.

For conciseness and convenience of the following description and without intended limitation, the invention is described herein primarily in embodiments directed to III-nitrides, and particularly in embodiments directed to GaN materials. This descriptive focus is only for example, and it should not be taken as limiting the invention.

It has been discovered that cleavage of composite substrates can be more complex in comparison to cleavage of homogenous substrates. Since composite substrates comprise two or more materials, there may exist a misorientation between the relative weak planes of cleavage between the two or more materials constituting the composite substrate. Such misorientation between the relative weak cleavage planes may result in poor separation of wafers and die, as well as poor semiconductor mirror facet formation.

Semiconductor materials (such as III-nitrides) used in fabricating laser diodes may benefit from having smooth flat mirror facets for producing efficient lasing. However, there may be difficulty in forming flat surfaces that smoothly cross the interface between an upper semiconductor material and a crystalline carrier substrate. This may be especially true for the most popular and inexpensive scribe and fracture method of mirror facet formation, due to possible crystal plane misorientation between the crystalline semiconductor material of the seed layer (e.g., III-nitride material) and the crystalline carrier substrate material.

For example, sapphire is a widely used carrier substrate material for the formation of III-nitride materials, but there may be concerns regarding the crystal misorientation between the III-nitride materials and the underlying sapphire carrier substrate. The sapphire may have crystal fracture planes that do not exactly coincide with the crystal fracture planes of III-nitride materials such as GaN formed on the sapphire, which may make scribe and fracture facet formation difficult.

FIG. 1 illustrates a fractured grown composite substrate formed according to various embodiments. A composite substrate 100 includes a carrier substrate 102, which may be formed of group II-VI, group IV and group III-V compound semiconductor materials, sapphire (a crystalline form of aluminum oxide), spinel (a crystalline form of magnesium aluminum oxide), silicon carbide (SiC), gallium arsenide (GaAs) silicon (Si), aluminum nitride (AlN), aluminum gallium nitride (AlGaN), gallium nitride (GaN), neodymium gallate, lithium gallate, and combinations thereof. The material of carrier substrate 102 may be crystalline and may be formed by atomic layer deposition (ALD), chemical vapor deposition (CVD), physical vapor deposition (PVD), sputtering, thermal evaporation, or other methods. An active III-nitride material layer 104 is shown as an illustrative crystalline gallium nitride (GaN) material grown directly on an illustrative sapphire carrier substrate 102. The sapphire carrier substrate 102 may be formed with any one of numerous potential crystal planes exposed on the top surface, and the crystal structure of the epitaxially grown GaN will depend in part on the carrier material orientation.

One potential consideration with the formation of optical devices is the desire for an optically flat surface oriented at a right angle to the direction of light propagation to provide a properly oriented mirror surface for efficient light production. The separation of individual semiconductor devices from a single wafer of a simple or a compound semiconductor is commonly achieved by cleaving the crystalline semiconductor substrate along well-defined crystal planes, typically indicated by what may be referred to as a major flat, and possibly a minor flat as well, formed at a specific location around the circumference of the typically circular wafer edge. Cleavage is often achieved by inscribing (also referred to as scribing) or scoring grooves into the surface of the wafer in the direction of the desired crystal fracture plane. This scoring may be performed by a diamond-tipped scribe or a laser beam, and a properly performed scoring operation matching the crystal plane of the substrate is commonly used to provide an inexpensive high quality mirror facet for the output of a semiconductor laser device. It is desired that the mirror facets of a laser be atomically flat and closely aligned parallel with each other to provide high device operational efficiency. Other methods of producing laser facets may include wet chemical etching, anisotropic wet chemical etching, plasma etching, anisotropic plasma etching, ion milling, and ion implantation.

Composite substrates may be composed of two or more materials, such as SiC on Si, which may be referred to as SiCOS, or GaN on sapphire, which may be referred to as GaNOS. Composite substrates can be utilized for III-nitride materials growth for improved cost, quality and device performance, but forming mirror facets in optical devices on composite substrates may be difficult. Formation of mirror facets is most efficiently obtained by cleavage along crystal planes. However, efficient cleavage of a composite substrate requires that the crystal orientations of the different materials forming the composite substrate be aligned with each other accurately enough that a fracture due to a surface scribe score continues from material to material without changing the direction of the fracture. The fracture face should be flat and smooth across the entire composite substrate thickness.

For example, III-nitride materials may be grown as a crystalline material by what may be referred to as an epitaxial growth process upon a crystal substrate formed of a different type of material. Since the materials are different, this may be referred to as hetero-epitaxial growth. III-nitrides may be grown on {0001} orientation surfaces of sapphire crystals. However, due to atomic line up during crystal growth, each of the sapphire crystallographic planes can be oriented 30 degrees away from the equivalent planes in the III-nitride material as shown in FIG. 1, where the carrier substrate 102 has a fracture front surface that deviates from the vertical angle of the III-nitride layer 104 by an angle 106. The carrier substrate 102 front surface has a horizontal direction that differs from the horizontal direction of the III-nitride layer 104 by an angle 108. Thus, the fracture front surface of the III-nitride material 104 and the carrier substrate 102, which is beneficially mirror smooth and flat, is not sufficiently flat for practical optical devices. Another way to express this (in the case where the III-nitride material is GaN and the carrier material is sapphire) is to say that sapphire m-planes are oriented 30 degrees away from the GaN m-planes. Angles 106 and 108 vary depending upon the different materials used in the composite substrate. Examples may include the vertical variation of the carrier substrate 102 fracture surface angle 106 from the III-nitride layer 104 ranging from 90 degrees (meaning no difference) in the case of {1100} SiC, to 71 degrees for the case of {111} Si, to 58 degrees for {1102} sapphire, to 55 degrees for {100} spinel. Angle 108 represents a horizontal difference between a grown III-nitride fracture surface and a carrier fracture surface, which may be about 30 degrees for the sapphire carrier as discussed previously and shown in FIG. 1, and zero degrees, meaning no difference in angle, for SiC, Si or spinel.

It is possible to form composite substrates by directly bonding a layer of a III-nitride material (or other semiconductor material) to the carrier material, or by the use of an intermediate bond assist layer, such as the bonding of two silicon layers by the use of an intervening silicon dioxide layer, or some other amorphous material without any crystal orientation. It may be difficult to bond the two different crystalline materials while obtaining adequate crystal plane orientation, and if an amorphous intermediate bonding layer is used, it may be difficult to control the direction of the cleavage plane in the amorphous material.

The presently described arrangement provides a structure and a method of forming the structure for a crystalline seed layer material, such as GaN, on a crystalline carrier material, such as sapphire, aligned such that a common cleavage plane exists between the two materials. The cleavage planes may be said to coincide. Such a common cleavage plane provides high quality reproducible scribe, or score, and fracture operation of such composite substrates and also provides high quality reproducible minor facets that are suitable for semiconductor laser devices. The sapphire carrier (or other carrier materials) may also have the cleavage plane perpendicular to the top surface of the GaN layer in addition to having coincident cleavage planes, a carrier substrate cleavage plane perpendicular to the top surface of the seed layer further improves cleavage and fracture yield as well as improving the quality of minor facet formation. The crystalline seed layer may be grown on an intermediate substrate and then bonded to the crystalline carrier material. Further, the coincident cleavage plane may be aligned perpendicular to a laser cavity formed in the GaN layer and perpendicular to the direction of light propagation in the laser diode cavity structure.

An example of a combination of materials that provide for a composite substrate suitable for semiconductor laser fabrication includes a III-nitride seed material such as GaN with cleavage planes of {1120}, which may be known as the a-plane, and a {1100} plane, which may be known as the m-plane. The seed layer is bonded to a crystalline carrier layer such as sapphire with cleavage planes {1120} (the a-plane), {1100} (the m-plane), {0001} (the c-plane), and {1102} (the r-plane). Other embodiments may include {111} {110} Si, and various III-V compounds, such as Gallium Arsenide having a {110} plane. In certain embodiments, there may be a bonding material layer between the seed and carrier layers, which may be an amorphous material such as silicon dioxide (SiO₂) or silicon nitride (Si₃N₄) layers that are less than 1 micron in thickness. With this arrangement, the coincident crystal planes provide an atomically smooth fracture surface upon cleavage through the entire thickness of the composite substrate. The specific fracture planes may be selected for the lowest cleavage energy Eγ necessary to separate a crystal along a given plane in Joules/m². There may be a cleavage plane perpendicular to the surface of the GaN layer in addition to the coincident planes, which may be aligned to be perpendicular to the direction of light propagation in the laser cavity.

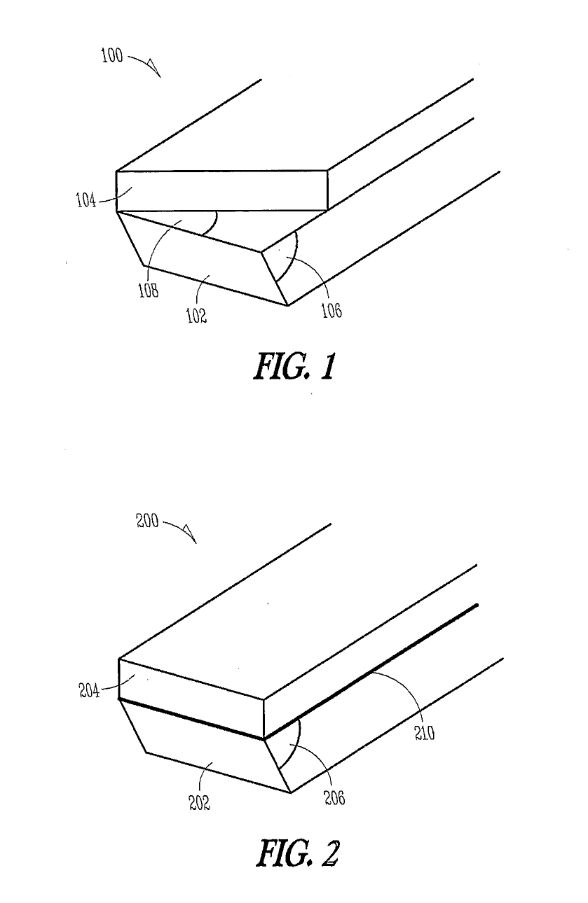

FIG. 2 illustrates a fractured bonded composite substrate formed according to various embodiments. A composite substrate 200 may have a sapphire carrier substrate 202 with a top surface crystal plane of {0001} and a front fracture plane of {1102}. There is a GaN layer 204 bonded to the top surface with a vertical front fracture plane due to a cleavage operation having an angle 206 to the sapphire {1102} fracture plane. The horizontal angle of the front surface fracture plane (previously shown as angle 108 in FIG. 1) is the same for the GaN layer 204 as for the sapphire carrier substrate 202, since the bonding in this illustrative embodiment includes aligning the {1100} front plane (m-plane) of the GaN to the {1102} front plane (r-plane) of the sapphire prior to bonding. This illustrative example does not provide an ideal solution for quality scribe and fracture for mirror surfaces since the vertical plane angle 206 is 58 degrees in this embodiment, and the resultant mirror surface may be partially non-perpendicular to the direction of light propagation. Various embodiments may include a bond assist layer (element 210 shown as a heavy line) disposed between the carrier substrate 202 and the GaN semiconductor layer 204. The bond assist layer may include a very thin amorphous layer, such as silicon oxide or silicon nitride or mixtures thereof, and have a thickness of less than 1 μm.

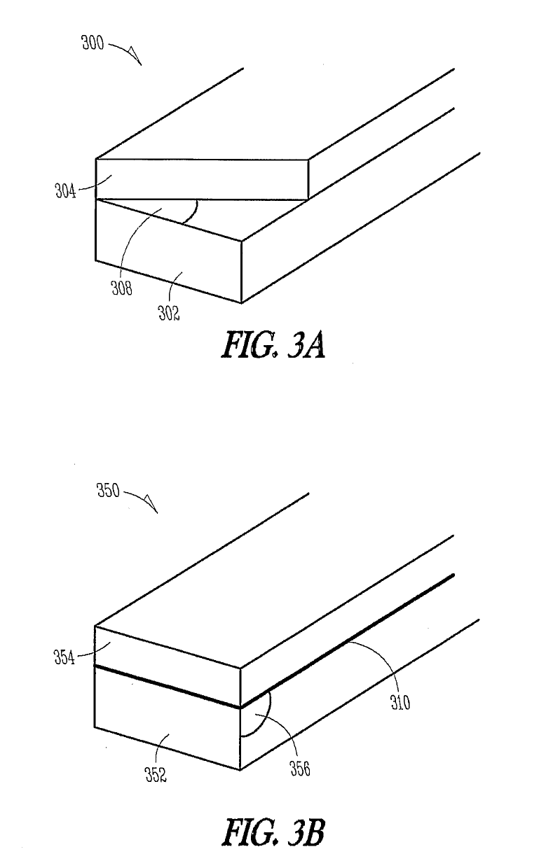

FIG. 3A illustrates a fractured grown composite substrate 300 formed according to various embodiments. A sapphire carrier substrate 302 is shown with a front fracture plane of {1100}. There is a GaN layer 304 epitaxially grown on the top surface with a vertical front fracture plane {1100} due to a cleavage operation having an angle 308 to the sapphire vertical front fracture plane. The angle 308 between the horizontal directions of the fracture planes for the GaN layer 304 and the sapphire carrier substrate 302 may be approximately 30 degrees and results in a cleavage fracture surface that is not as flat and smooth as desirable for optical devices.

FIG. 3B illustrates a fractured bonded composite substrate 350 formed according to various embodiments. A sapphire carrier substrate 352 is shown with a front fracture plane having a crystal orientation of {1100}. There is a GaN layer 354 bonded to the top surface with a vertical front fracture plane crystal orientation of {0001} due to a cleavage operation having an angle 356 to the sapphire {1100} fracture plane. In the illustrative embodiment, angle 356 is 90 degrees, meaning that the two front surfaces have coincident fracture planes and the surface is smooth and flat.

In some embodiments, the GaN layer 354 is bonded to the sapphire carrier layer 352 using a bond assist layer 310. The use of the m-plane sapphire may provide easier cleavage operations and higher quality mirror facets for the light transmission path in an optical device such as a laser. The use of a composite substrate having both the m-plane of the GaN and the m-plane of the sapphire aligned to each other provides a simple and high quality front mirror fracture surface for optical devices that is perpendicular to the surface of the composite substrate 350 and may be formed perpendicular to the light propagation direction of a laser device. In other embodiments, the a-planes (i.e., the {1120} crystal direction) of GaN and sapphire layers may be aligned, or the a-plane of the GaN layer may be aligned to the m-plane of the sapphire layer, or vice versa may be used to obtain coincident cleavage planes.

The GaN layer 354 may be either a seed layer for future epitaxial crystal growth or a full thickness device layer bonded to the sapphire carrier layer 352. In the case where the GaN layer is bonded to the carrier layer, the desired cleavage planes are aligned to be coincident. This may be done by use of a GaN donor structure that is decorated to provide an external indication of the crystal orientation to be used as a marker during the alignment of the two crystalline layers during bonding. The carrier layer may also be decorated to form secondary crystal orientation indicators for use in alignment to the GaN layer. The crystalline orientation of the GaN and sapphire layers may be determined by x-ray diffraction, electron backscatter diffraction (EBSD), glancing angle x-ray diffraction (GAXRD), wet chemical etching, or other methods. The determined crystal orientation may be marked on the GaN and sapphire layers by marks formed by scribing with diamond tips or lasers, wet chemical etching the surface, plasma etching the surface, grinding flats on the edges of the layers, or mixed orientated growth of the surface, or other methods. The use of wet chemical etching may result in preferential etching along selected crystal planes and thus determine and mark the crystal planes in a single operation. The alignment of the GaN layer and the sapphire layer in accordance with the crystal orientation marks may be performed using other methods.

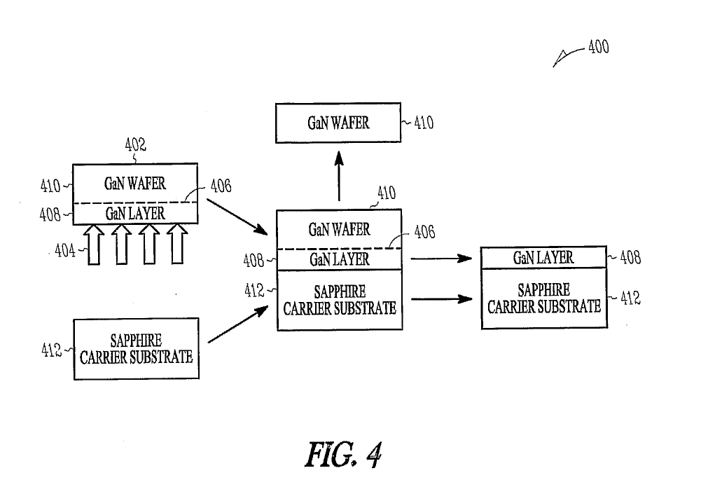

The donor material for producing a GaN seed layer such as 354 of FIG. 3B may comprise a free-standing (FS) wafer of GaN, although it should be noted that the described embodiments are not limited to any particular crystalline material or carrier substrate. A thin seed layer may be used as a base layer for later formation of a GaN active device layer as the use of FS wafers may be expensive. Many methods may be used to separate a thin seed layer from a FS wafer of GaN. FIG. 4 illustrates a composite substrate 400 formed according to various embodiments.

Obtaining a thin seed layer of GaN having a selected thickness for attachment to a sapphire carrier substrate may include weakening a region inside free-standing GaN wafer 402 using an ion implantation 404 of selected ions having an energy selected to form a weakened region 406 (shown as a dotted line) inside the material of GaN wafer 402. Ions appropriate for implantation may include hydrogen or helium having an energy selected to cause weakness at the desired depth, forming a weakened region for separation of the GaN wafer 402 into a remaining portion of the GaN wafer 410 and thin GaN layer 408 for use as a seed layer.

The GaN wafer 402 including the attached thin GaN layer 408 may have the crystal orientation determined and marked as discussed above and be bonded to a carrier substrate 412 having a determined and marked crystal orientation. The bonding may include attaching the thin GaN layer 408 to a top surface of the sapphire carrier substrate 412. The bonding may include a bond assist layer (not shown) and may align the m-planes of the GaN wafer 402 and the m-planes of the sapphire carrier substrate 412 to be coincident. Fracturing GaN wafer 402 to form and separate thin GaN layer 408 and remainder GaN wafer 410 may occur either before or after bonding to the sapphire carrier substrate 412. Fracturing may occur by application of mechanical stress, thermal stress, electrostatic stress, laser irradiation, or various combinations.

The thin GaN layer 408 having the selected thickness on the sapphire carrier substrate 412 may be a seed material layer with a selected thickness formed of any III-nitride in addition to the shown gallium nitride (GaN), such as indium gallium nitride (InGaN), or aluminum gallium nitride (AlGaN), and may be polar, non-polar or semi-polar. In a polar material, the surface may be either Ga-polar or N-polar, and the opposite surface may be the opposite polarity. The remaining GaN wafer 410 may be implanted again to form additional layers similar to thin GaN layer 408 for manufacture of additional devices.

An optical device can be formed using the composite substrate 400 with formation of optical devices in the GaN layer 408, or if GaN layer 408 is a seed layer, then a device layer may be formed to complete the optoelectronic device. A device layer may be formed of multi-quantum well structures using III-nitride materials with a top surface selected to be either Ga-polar or N-polar. The Ga-polar face may yield improved device quality.

The device layer may be processed in such a way as to form a plurality of device structures, for example, by utilizing well-known semiconductor processing methods such as etching (wet or dry), metallization and photolithography. The device layer may be processed in such a way so as to form a plurality of light-emitting devices, such as a plurality of laser diodes. The formation of laser diodes can be processed in such a way (i.e., through alignment during photolithographic processes) so that the laser cavity of the device (i.e., the direction of light propagation within the device) is aligned perpendicular to the coincident cleavage planes of the composite substrate upon which they are formed. Forming of laser diodes utilizing alignment processes with the composite substrate as outlined can result in the formation of high quality mirror-like laser facets.

FIG. 5 illustrates a simplified diagram for an illustrative electronic system 500 having one or more devices including an optical signal transmission device according to various disclosed embodiments. The electronic system 500 may include a controller 502, a bus 504, and an electronic device 506, where bus 504 provides electrical or optical signal transmission between controller 502 and electronic device 506. In various embodiments, the controller 502 and/or electronic device 506 may include optical data transmission devices. Electronic system 500 may include information handling, wireless, telecommunication, fiber optic, automotive, electro-optic, mobile electronics, handheld devices, and computer systems. Electronic device 506 may comprise a microprocessor, a floating point unit, an arithmetic logic unit, a memory device, a multiplexer, an address decoder, a power controller, or any other electronic device used in computer, telecommunication, sensor, display and other products.

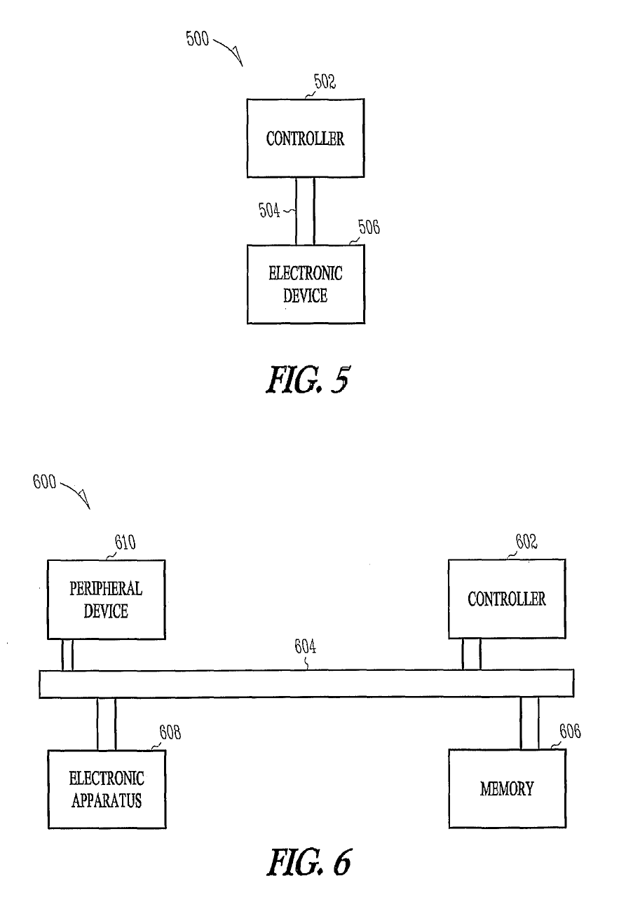

FIG. 6 depicts a diagram of an electronic system 600 having at least one device formed in accordance with the disclosed embodiments, including a controller 602 and a memory 606. Controller 602 and/or memory 606 may include a non-volatile memory device. The system 600 may also include an electronic apparatus 608 and a bus 604, where the bus 604 may provide data transmission between controller 602 and electronic apparatus 608, and between controller 602 and memory 606. The bus 604 may include an address, a data bus, and a control bus, each independently configured. The bus 604 may use common conductive lines for providing address, data, and/or control, or optical transmission lines, the use of which may be regulated by the controller 602. In some embodiments, the electronic apparatus 608 may include additional memory devices configured similar to the memory 606. Some embodiments may include an additional peripheral device 610 coupled to the bus 604. In an embodiment, the controller 602 comprises a processor. Any of the controller 602, the memory 606, the bus 604, the electronic apparatus 608, and peripheral devices 610 may include an optical transmission device formed in accordance with the disclosed embodiments.

System 600 may include, but is not limited to, information handling devices, telecommunication systems, mobile electronic devices such as laptop computers, handheld personal electronic devices such as personal digital assistants (PDA) and palm tops, handheld communication devices such as cell phones, digital cameras and DVD recorders, and computers. Peripheral devices 610 may include displays, additional storage memory, or other control devices that may operate in conjunction with controller 602 and/or memory 606.

The present subject matter includes a method for forming a carrier substrate with a seed layer and forming an active optoelectronic layer on the seed layer. The seed layer may be formed by bonding a wafer of a III-nitride material to the carrier substrate, where the bonding may include determining a first crystal direction in the seed layer and aligning the first crystal direction to a predetermined direction of the carrier substrate to obtain coincident fracture planes in the two materials upon cleaving to form mirror facets for a laser. There may be direct bonding between the seed layer and the carrier substrate, or there may be a bond assist material layer to improve bond strength. The seed layer may include a III-nitride semiconductor having a selected thickness, such as a layer of gallium nitride with a formula including GaN. Forming the GaN layer may include bonding a free-standing wafer of GaN to the carrier layer and then thinning the GaN to the selected thickness, or include ion implanting to form a damaged region within the GaN.

An optical device may comprise sapphire with orientation marks on the carrier and a III-nitride layer such as gallium nitride (GaN), indium gallium nitride (InGaN), aluminum gallium nitride (AlGaN), aluminum oxide, silicon carbide, silicon, neodymium gallate, and lithium gallate. The III-nitride layer has a crystal orientation and is aligned to the carrier substrate orientation. The III-nitride layer may have a surface that is non-polar, semi-polar, Ga-polar or N-polar, and a crystalline orientation of an a-plane, a c-plane, an m-plane, or an r-plane. The m-plane of the carrier substrate may be aligned coincident to the m-plane of the III-nitride layer, or aligned to an r-plane, or other possible coincident planes that form a flat smooth fracture surface upon cleaving that are perpendicular to the top surface and to a light propagation direction.

The present subject matter includes an optical device substrate with a crystalline sapphire carrier substrate having alignment marks indicating crystal orientation such as an a-plane, a c-plane, an m-plane, and an r-plane, and aligned coincident to a selected crystal orientation of the gallium nitride layer. The crystalline gallium nitride layer may be bonded directly to the crystalline sapphire carrier substrate or may use a bond assist layer such as silicon oxide or silicon nitride. The bond assist layer may be less than 1 micron in thickness. The GaN may have a top surface having a Ga polarity, or an N polarity or no polarity.

The detailed description refers to the accompanying drawings that show, by way of illustration, specific aspects and embodiments in which the present disclosed embodiments may be practiced. These embodiments are described in sufficient detail to enable those skilled in the art to practice aspects of the present invention. Other embodiments may be utilized, and structural, logical, and electrical changes may be made without departing from the scope of the disclosed embodiments. The various embodiments are not necessarily mutually exclusive, as some embodiments can be combined with one or more other embodiments to form new embodiments.

Although specific embodiments have been illustrated and described herein, it will be appreciated by those of ordinary skill in the art that any arrangement that is calculated to achieve the same purpose may be substituted for the specific embodiments shown. This application is intended to cover any adaptations or variations of embodiments of the present invention. It is to be understood that the above description is intended to be illustrative, and not restrictive, and that the phraseology or terminology employed herein is for the purpose of description and not of limitation. Combinations of the above embodiments and other embodiments will be apparent to those of skill in the art upon studying the above description. The scope of the present disclosed embodiments includes any other applications in which embodiments of the above structures and fabrication methods are used. The detailed description is, therefore, not to be taken in a limiting sense and the scope of the present invention is defined only by the appended claims, along with the full scope of equivalents to which such claims are entitled.

1. A method, comprising:
forming a carrier substrate;
forming a seed layer;
bonding the seed layer on the carrier substrate;
wherein bonding includes determining a first crystal direction in the seed layer and aligning the first crystal direction to a predetermined direction of the carrier substrate.

2. The method of claim 1, wherein the first crystal direction in the seed layer and the predetermined direction of the carrier substrate comprise crystalline cleavage planes.

3. The method of claim 1, further comprising forming an active optoelectronic layer on the seed layer.

4. The method of claim 3, further comprising forming a plurality of laser diodes utilizing the active optoelectronic layer wherein the direction of light propagation within the plurality of laser diodes is perpendicular to the first crystal direction.

5. The method of claim 1, further comprising forming a mark on the carrier substrate indicating the predetermined crystal direction and aligning the first crystal direction in the seed layer relative to said mark.

6. The method of claim 1, wherein bonding includes direct bonding between the seed layer and the carrier substrate.

7. The method of claim 1, wherein forming the seed layer includes forming a layer of a III-nitride semiconductor having a selected thickness.

8. The method of claim 1, wherein forming the carrier substrate includes providing a sapphire substrate.

9. The method of claim 7, wherein forming the seed layer includes bonding a wafer comprising a III-nitride semiconductor having more than the selected thickness to the carrier substrate and thinning the wafer comprising the III-nitride semiconductor to the selected thickness.

10. The method of claim 1, wherein forming the carrier substrate includes forming a crystalline orientation plane having at least one of an a-plane, a c-plane, an m-plane, and an r-plane.

11. The method of claim 10, further including aligning at least one crystal orientation plane in the seed layer coincident to at least one selected crystal orientation plane of the carrier substrate.

12. The method of claim 10, further including aligning an m-plane of the carrier substrate to an m-plane of the seed layer.

13. The method of claim 10, further including aligning an m-plane of the seed layer to an r-plane of the carrier substrate.

14. A composite optical device substrate, comprising:
a crystalline carrier substrate having at least one alignment mark indicating a selected crystal orientation; and
a crystalline seed layer disposed on the crystalline carrier substrate and having a crystal plane aligned coincident with the crystal orientation of the carrier substrate.

15. The composite optical device substrate of claim 14, wherein the crystalline seed layer is bonded directly to the crystalline carrier substrate.

16. The composite optical device substrate of claim 14, further including a bond assist layer disposed between the crystalline seed layer and the crystalline carrier substrate.

17. The composite optical device substrate of claim 16, wherein the bond assist layer includes at least one of silicon dioxide and silicon nitride.

18. The composite optical device substrate of claim 14, wherein the crystalline carrier substrate comprises sapphire.

19. The composite optical device substrate of claim 14, wherein the crystalline seed layer comprises gallium nitride.

20. The composite optical device substrate of claim 14, wherein the selected crystal orientation is selected from a list consisting of an a-plane, a c-plane, an m-plane and an r-plane.
